(19) United States
(12) Patent Application Publication
(10) Pub. No.: US 2005/0235177 A1
(43) Pub. Date: Oct. 20, 2005

(54) Path delay test method

(75) Inventors: Yasushi Ohara, Yokohama-shi (JP); Akimitsu Shimamura, Osaka (JP); Tetsuya Abe, Kyoto-shi (JP); Hideo Imai, Kyoto-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/109,702

(22) Filed: Apr. 20, 2005

(30) Foreign Application Priority Data
Apr. 20, 2004 (JP) P2004-123809

(51) Int. Cl. G11B 5/00; G06K 5/04; G11B 20/20; G01R 31/28

(52) U.S. Cl. 714/700

(57) ABSTRACT

From layout information which was generated from a net list of a semiconductor integrated circuit, extracted are a critical path to guaranteed operating frequency and physical information such as wiring congestion and via density, and on the basis of the physical information, a place to be easily broken down is specified, and a critical path, in which a delay fault is envisaged, is sorted out from critical paths, and a test pattern is generated only as to the selected critical path. On that occasion, by use of automatic test pattern generation software, and by use of a weighting application verification model which is obtained from critical path sorting information based on physical information, a weighting factor of a critical path is given.

This application is based on Japanese Patent Application No. 2004-123809, which is incorporated herein by reference.

### BACKGROUND OF THE INVENTION

1. Field of the Invention

This invention relates to a test method of a semiconductor product, and particularly, relates to a test pattern generating technology which improves detection capability for a delay fault due to speeding up of a semiconductor integrated circuit and miniaturization of a process.

2. Description of the Related Art

In a shipping test of semiconductor products, various tests are carried out in order to guarantee high quality, and a product for which a fault was detected is excluded as a defective product. As kinds of faults which are judged in a test, there are a stuck-at fault, a delay fault and so on.

The stuck-at fault means such a fault that a signal wiring short-circuits with a power supply at the time of manufacturing a semiconductor, it is fixed to a “L” level or a “H” level. In order to detect the suchlike stuck-at fault, a semiconductor integrated circuit incorporates a test mode, and it is designed in such a manner that it is possible to freely control and observe an internal signal of a semiconductor integrated circuit from an external terminal by use of a semiconductor tester etc. at the time of the test mode.

In order to detect the stuck-at fault, generally employed is such a scan test that storage devices such as flip-flops, which are incorporated in a semiconductor integrated circuit, are connected serially to configure a scan chain at the time of the test mode, and data is supplied to a combination circuit in a semiconductor integrated circuit and a test is carried out.

That is, a test pattern is inputted to and held in a storage device in a semiconductor integrated circuit from an input terminal by a semiconductor tester, and this held test pattern is supplied to a combination circuit in a semiconductor integrated circuit, and data, which passed through the combination circuit, is imported into the storage device again, and the imported data is transported up to an output terminal of the semiconductor integrated circuit, and a logical expected value and data which is outputted to the output terminal are compared by a semiconductor tester, and it is judged whether a fault is generated or not.

FIG. 15 is a flow chart which shows a scan test pattern generating method in a scan test. Firstly, HDL (Hardware Description Language) 101 is logically combined in a step 102, to prepare a net list 103 of a gate level. The prepared net list and scan path test restriction 1501 in which clock, reset, mode setup etc. are described at the time of a scan path test are processed by ATPG (Automatic Test Pattern Generator) in a step 112, and thereby, a stuck-at fault test pattern 113 for testing a stuck-at fault of a semiconductor is generated.

However, in a stuck-at fault inspection, it is possible to detect such a fault that a signal wiring is fixed to an “L” level or an “H” level when short-circuited with a power supply, but it is not possible to guarantee a product specification relating to operating frequency which a semiconductor product guarantees. As a fault in which it is not possible to satisfy operating frequency which a product guaranteed, there is a delay fault. The delay fault is such a thing that circuit delay increases substantially to a design specification due to some sort of factors in a semiconductor circuit structure and a semiconductor manufacturing process.

In related art, a delay fault is detected by use of a system verification pattern which conforms to an actual use condition of a semiconductor product. However, as to a test by use of a system verification pattern, there is such demerits that its development requires time, and that a test pattern becomes a gigantic size in order to carry out a systematic operation and cost increases, and it is difficult to apply it to all actual operating functions.

Nowadays, considering increases of development schedule and cost because of realizing a large-scale semiconductor integrated circuit, it becomes gradually difficult to realize an implementation of a delay fault test to an entire circuit. On one hand, a fault, which is classified as a delay fault, becomes plentiful, because of miniaturization of a process. Thus, a test of the delay fault has become indispensable in order to guarantee high quality. As its countermeasure, in related art, such a technology has been developed that a delay circuit for use in a test, which has equivalent delay time to a critical path in a semiconductor device, is disposed and maximum operating frequency is measured (e.g., see, JP-A-2001-274334).

FIG. 16 is a block diagram which shows a text circuit configuration in the above-described related delay fault test method. A semiconductor integrated circuit 1601 is composed of a stepwise logic circuit 1602 and a combination circuit 1603 including a critical path, but a critical path of the combination circuit 1603 is severe in timing, and therefore, it is not possible to easily insert a test confirmation circuit.

In order to easily test this, critical path information of the combination circuit 1603 is analyzed at the time of design, and a cell of a circuit configuration having an equivalent delay characteristic to this is put into an inside of the semiconductor integrated circuit 1601 as a test critical path circuit 1604 which can be easily monitored from an external input/output terminal. By this means, it is possible to carry out a pseudo test of a critical path.

A current semiconductor integrated circuit, in order to correspond to demands of multiple functions and price reduction, carries out SoC (System on Chip) development in which resources, which have been already designed, are also used as an IP (Intellectual Property) core, and various IP cores are integrated, to realize multiple functions, an application of a ultra fine process for absorbing chip size increase due to speeding up and large-scale integration of a semiconductor integrated circuit, and so on.

In the past, a good many semiconductor integrated circuits with high operating frequency do not exist, and a defect is detected by a test pattern of a high stuck-at fault detection rate and a few actual operation test pattern, and thereby, it was possible to hold down a market defective fraction in many semiconductor integrated circuits.

However, there was such a problem that, because of current speeding up of operating frequency and process miniaturization, a market defective fraction becomes high, even in a product which was sorted out as a defective product by a test pattern of a high stuck-at fault detection rate and a few actual operation test pattern. In fact, a wiring soft open defect and a via connection defect occurred in a fine process, and therefore, a delay characteristic was fluctuated significantly.

As to the above-described related technology in which a test delay circuit, which has equivalent delay time to a critical path in a semiconductor device, is disposed and maximum operating frequency is measured, there is such an advantage that the number of design man-hours is reduced, but it has such a drawback that cost increases due to circuit size increase, and a circuit, which is actually used, is not inspected.

### SUMMARY OF THE INVENTION

The invention aims to provide a path delay test method realizing test pattern generation which is capable of detecting a delay fault, which arises from speeding up of a semiconductor circuit and miniaturization of a process and is difficult to be detected by a related test method, and enabling high quality product shipping without introducing increase of the number of development man-hours.

A path delay test method of the invention is a method which extracts physical information of a circuit and a critical path to guaranteed operating frequency, from layout information which was generated by a net list of a semiconductor integrated circuit, and sorts out a critical path in which a delay fault is envisaged, from the critical path, on the basis of the physical information, and generates a test pattern only to the critical path which was sorted out.

According to the above-described delay test method, as to a critical path which was extracted by use of layout information after physical combining, a test pattern is reduced, by reducing and applying weighing to a path. A test pattern is generated only as to a critical path which was limited by this means, and a shipping test is carried out, and thereby, it is possible to reduce the number of design man-hours and test cost over maintaining quality of a product.

It is, in the path delay test method of the invention, a method in which generation of the test pattern is carried out by use of automatic test pattern generation software. On the occasion of generation of a test pattern in the path delay test method of the invention, a weighting application verification model which is obtained from critical path sorting information based on physical information gives a weighting factor of a critical path to automatic test pattern generation software.

According to the above-described path delay test method, by giving a weighting factor of a path based on physical information extracted from layout information, refinement freedom degree of a limited path increases, and it becomes possible to flexibly correspond to tool application.

It is a method in which whether it is in a higher order of a critical path is used as a judgment condition, in sorting of a critical path in the path delay test of the invention. It is a method in which whether there exists a cell with high current drive capability in a critical path is used as a judgment condition, in sorting of a critical path in the path delay test of the invention. The cell with high current drive capability has a low ON-resistance of a transistor, and, in case that process fluctuation was generated in a via resistance and a wiring resistance, receives its influence widely, but according to the above-described path delay test, it is possible to take a countermeasure to this.

It is a method in which whether there exists a place which was connected by a single via in a critical path is used as a judgment condition, in sorting of a critical path in the path delay test method of the invention. At the place which was connected by a single via, a resistance value increases clearly in case that a via connection defect occurred, and therefore, there is high possibility that a delay fault is realized, but according to the above-described path delay test method, it is possible to take its countermeasure.

It is a method in which whether a critical path exists in an area where a via density is high is used as a judgment condition, in sorting of a critical path in the path delay test method of the invention. At the place with high via density, connection defect probability of a via is high, but according to the above-described path delay test method, it is possible to take its countermeasure.

It is a method in which whether a critical path exists in an area where a gate density is high is used as a judgment condition, in sorting of a critical path of the path delay test method of the invention. At the place with high gate density, via connection defect probability and soft short probability are high, but according to the above-described path delay test method, it is possible to take a countermeasure to this.

It is a method in which whether a critical path exists in an area where a wiring density is high is used as a judgment condition, in sorting of a critical path in the path delay test method of the invention. At the place with high wiring density, wiring soft short probability is high, but according to the above-described path delay test method, it is possible to take a countermeasure to this.

A path delay test method of the invention is a method which extracts a critical path to guaranteed operating frequency, from a logically combined net list of a semiconductor integrated circuit, and sorts out a critical path in which a delay fault is envisaged, from the critical path, on the basis of circuit information of the logical combining, and generates a test pattern only to the critical path which was sorted out. In case of such a design policy that physical consideration is applied to a wiring, a via etc. and a margin was setup sufficiently, a test pattern is generated by timing information after physical combining, without depending on timing information after physical combining, and thereby, it is possible to shorten a development schedule substantially.

According to the above-described path delay test method, as to a critical path which was extracted by use of layout information after physical combining, a test pattern is reduced, by reducing and applying weighing to a path. A test pattern is generated only as to a critical path which was limited by this means, and a shipping test is carried out, and thereby, it is possible to reduce the number of design man-hours and test cost over maintaining quality of a product.

It is, in the path delay test method of the invention, a method in which generation of the test pattern is carried out by use of automatic test pattern generation software. On the occasion of generation of a test pattern in the path delay test method of the invention, a weighting application verification model which is obtained from critical path sorting information based on physical information gives a weighting factor of a critical path to automatic test pattern generation software.

According to the above-described path delay test method, a weighting factor of a path is given by use of a weighting application verification model which is obtained from critical path sorting information based on circuit information of physical combining, and thereby, refinement freedom degree of a limited path increases, and it becomes possible to flexibly correspond to tool application.

It is a method in which whether it is in a higher order of a critical path is used as a judgment condition, in sorting of a critical path in the path delay test of the invention. It is a method in which whether there exists a cell with high current drive capability in a critical path is used as a judgment condition, in sorting of a critical path in the path delay test of the invention. The cell with high current drive capability has a low ON-resistance, and, in case that process fluctuation was generated in a via resistance and a wiring resistance, receives its influence widely, but according to the above-described path delay test, it is possible to take a countermeasure to this.

A test method of a semiconductor integrated circuit of the invention is a method in which sorting of a delay fault test pattern is carried out in consideration of delay increase due to a structural defect of a semiconductor integrated circuit.

According to the invention, as to a critical path which was extracted by use of layout information after physical combining, a test pattern is reduced, by reducing and applying weighing to a path, and a test pattern is generated only to this limited critical path, and thereby, it is possible to effectively generate a delay fault test pattern, and by carrying out a shipping inspection by use of this test pattern, a substantial improvement effect is obtained in all of a quality aspect, a development schedule aspect, and a cost aspect.

### BRIEF DESCRIPTION OF THE DRAWINGS

FIG. 1 is a flow chart which shows a path delay test method which relates to a first embodiment of the invention;

FIG. 2 is a flow chart showing such a configuration that, in the path delay test method of the first embodiment, automatic generation of a delay fault test pattern is carried out by ATPG;

FIG. 3 is a flow chart showing such a configuration that, in the path delay test method which relates to the first embodiment of the invention, a path weighting factor is inputted on the occasion of automatic generation of a delay fault test pattern by ATPG;

FIG. 4 is a flow chart showing such a configuration that, in the path delay test method which relates to a second embodiment of the invention, a higher order path of critical path is extracted in accordance with a delay value of a path;

FIG. 5 is a flow chart showing such a configuration that, in the path delay test method which relates to the second embodiment of the invention, a path, where there exists a cell with high current drive capability of a transistor, is extracted;

FIG. 6 is a flow chart showing such a configuration that, in the path delay test method which relates to the second embodiment of the invention, a path, where there exists a place which was connected by a single via, is extracted;

FIG. 7 is a flow chart showing such a configuration that, in the path delay test method which relates to the second embodiment of the invention, a path with high via density is extracted;

FIG. 8 is a flow chart showing such a configuration that, in the path delay test method which relates to the second embodiment of the invention, a path with high gate density is extracted;

FIG. 9 is a flow chart showing such a configuration that, in the path delay test method which relates to the second embodiment of the invention, a path with high wiring density is extracted;

FIG. 10 is a flow chart which shows a path delay test method relating to a third embodiment of the invention;

FIG. 11 is a flow chart showing such a configuration that, in the path delay test method which relates to the third embodiment of the invention, automatic generation of a delay fault test pattern is carried out by ATPG;

FIG. 12 is a flow chart showing such a configuration that, in the path delay test method which relates to the third embodiment of the invention, a path weighting factor is inputted on the occasion of automatic generation of a delay fault test pattern by ATPG;

FIG. 13 is a flow chart showing such a configuration that, in the path delay test method which relates to a fourth embodiment of the invention, a higher path of critical path is extracted in accordance with a delay value of a path;

FIG. 14 is a flow chart showing such a configuration that, in the path delay test method which relates to the fourth embodiment of the invention, a path, where there exists a cell with high current drive capability of a transistor, is extracted;

FIG. 15 is a flow chart which shows a scan test pattern generating method in a scan test; and

FIG. 16 is a block diagram which shows a test circuit configuration in a related delay fault test method.

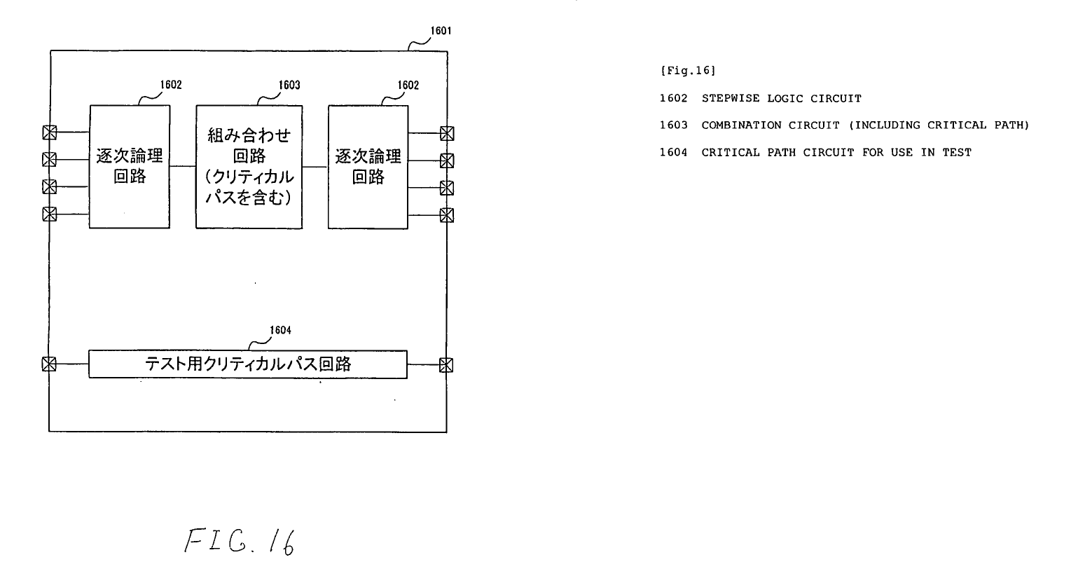

### DETAILED DESCRIPTION OF THE PREFERRED EMBODIMENTS

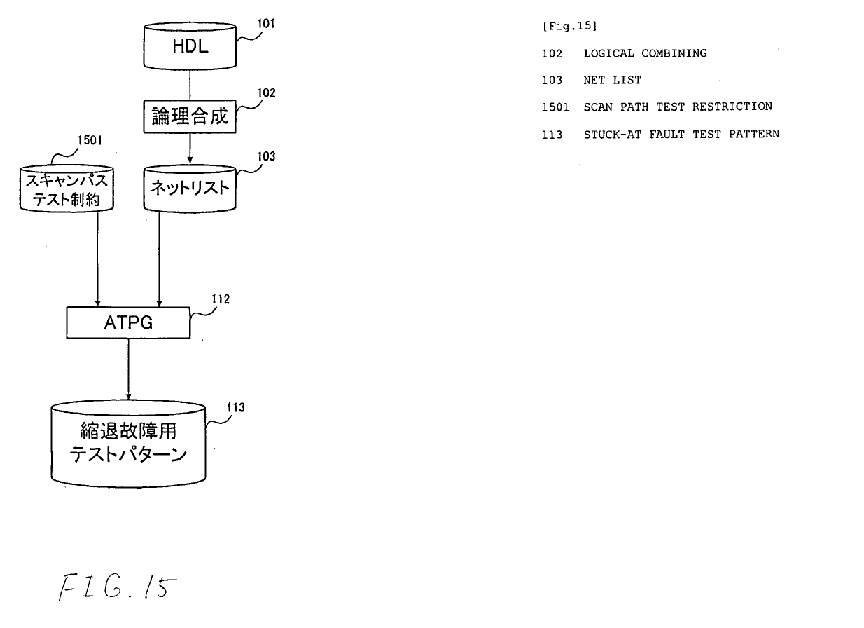

Hereinafter, an embodiment of the invention will be described with reference to drawings. Meanwhile, in the following description of the drawings, identical or similar reference numerals and signs are applied to identical or similar portions, and as to identical portions, overlapped explanations will be omitted. In addition, much the same is true on portions which are identical to those in FIG. 15.

### First Embodiment

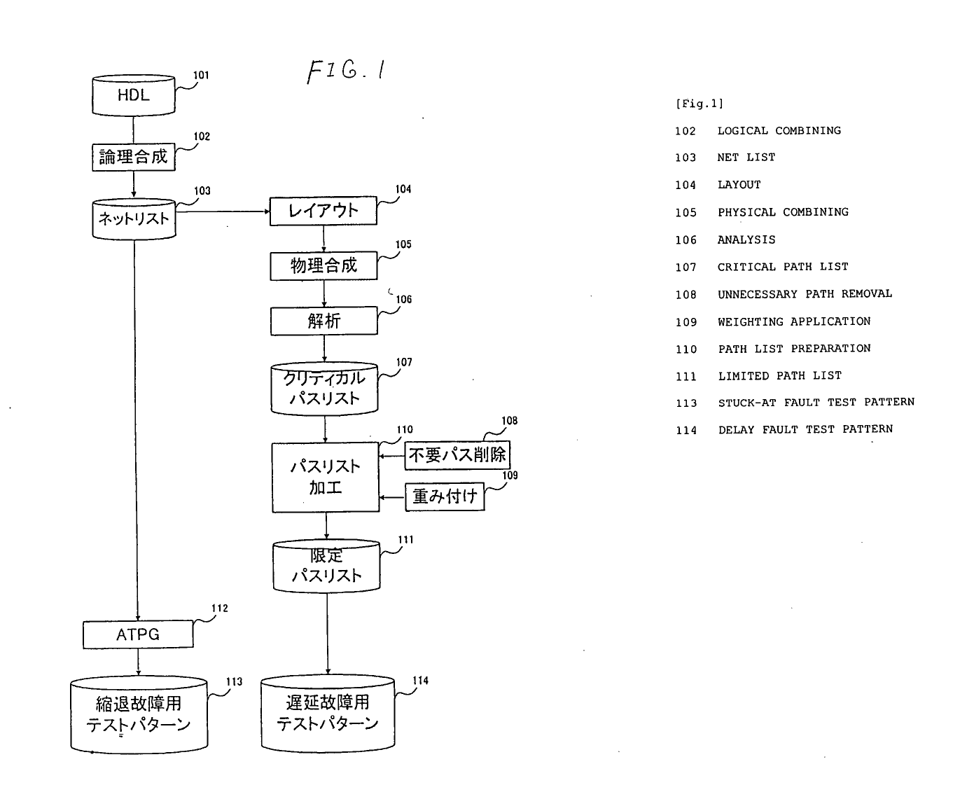

FIG. 1 is a flow chart which shows a path delay test method which relates to a first embodiment of the invention. In FIG. 1, 101 designates HDL (Hardware Description Language) by which a circuit was described, and 102 designates a logical combining process of combining HDL 101 by use of a logical combining tool and generating a net list of a gate level, and 103 designates a net list which was generated in the logical combining process 102, and 104 designates a layout process of actually laying out the net list by a layout tool, and 105 designates a physical combining process of checking timing so as for a gate which was located by the layout process 104 to be able to operate with operating frequency pursuant to an actual function, and carrying out relocation and logical structure re-assembly. The foregoing is an automatic design process of a commonly used semiconductor integrated circuit.

Further, 106 designates a timing analyzing process after the physical combining process 105, and 107 designates a critical path list which is extracted from physical information which can be confirmed by the analyzing process 106, and 108 designates a process of removing a test unnecessary path by using physical analysis information such as timing analysis, and 109 designates a process of applying weighting of a delay factor to a path and a cell, and 110 designates a path list preparing process of limiting a test implication object path by carrying out weighting to path information and sorting of a path, and 111 designates a path list which was limited as a test implementation object, and 112 designates an ATPG (Automatic Test Pattern Generator) process of generating a stuck-at fault test pattern, and 113 designates the generated stuck-at fault test pattern.

Here, as the physical information which can be confirmed by the analyzing process 106, there are circuit structure information, load information, via connection information, wiring information etc. of a semiconductor integrated circuit, and they are used for sorting out a critical path in which a delay fault is envisaged, from critical path candidates which are extracted by mechanical processing.

In the path delay test method of this embodiment, such a path that timing is critical is extracted by use of layout information after physical combining, and a path is reduced and weighting is applied to the extracted critical path, and thereby, a test pattern is reduced. A test pattern is generated only as to a critical path which was limited by this means, and a shipping test is carried out, and thereby, it is possible to reduce the number of design man-hours and test cost over maintaining quality of a product.

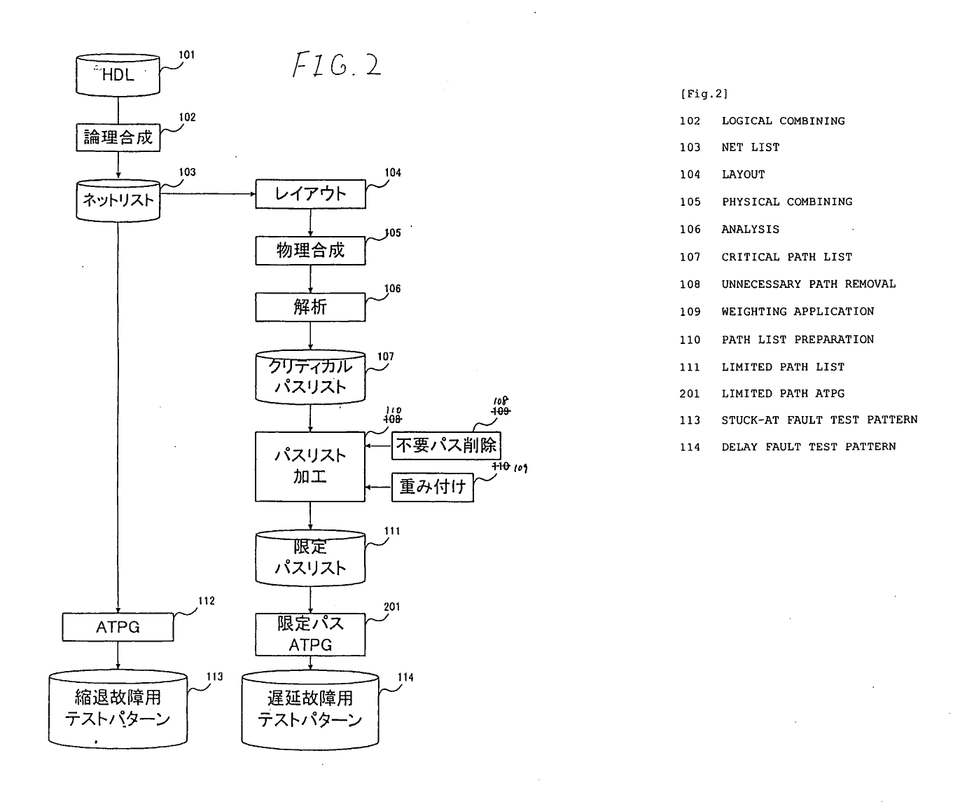

FIG. 2 is a flow chart showing such a configuration that, on the occasion of generating the delay fault test pattern 114 from the limited path list 111, in the path delay test method of this embodiment, a test pattern is automatically generated by a limited path ATPG process 201.

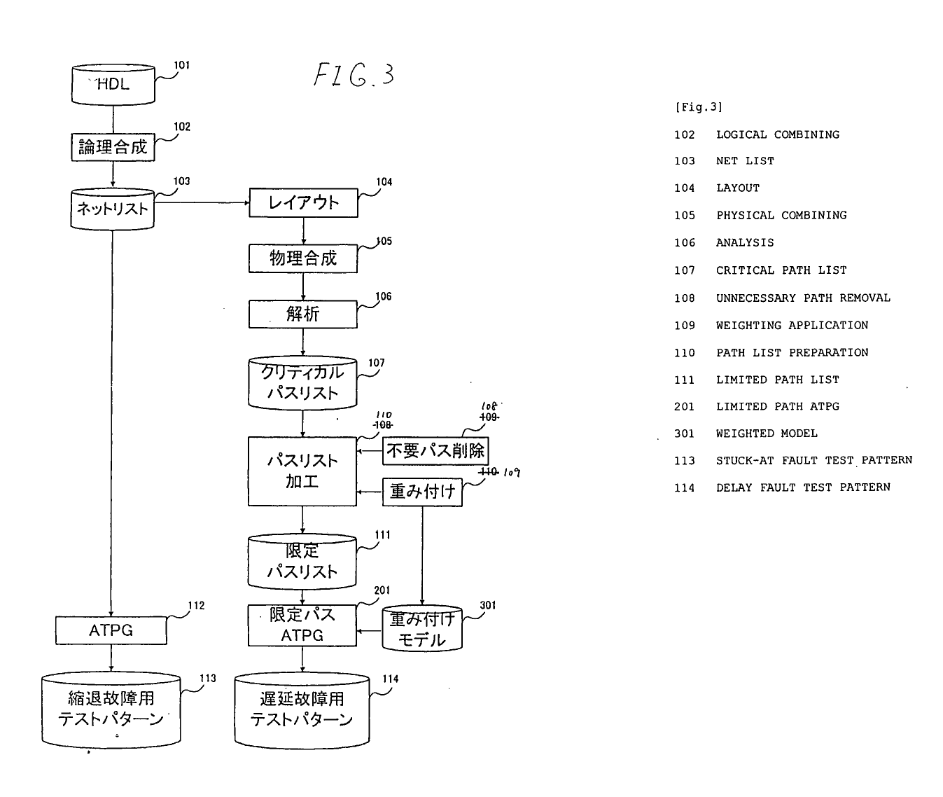

FIG. 3 is a flow chart showing such a configuration that, on the occasion of automatic generation of a delay fault test pattern by the limited path ATPG process 201, a path weighting factor is further inputted into the limited path ATPG process 201, by use of a weighted model 301 which is obtained from the process 109. By giving a path weighting factor in this manner, refinement freedom degree of a limited path increases, and it becomes possible to flexibly correspond to tool application.

### Second Embodiment

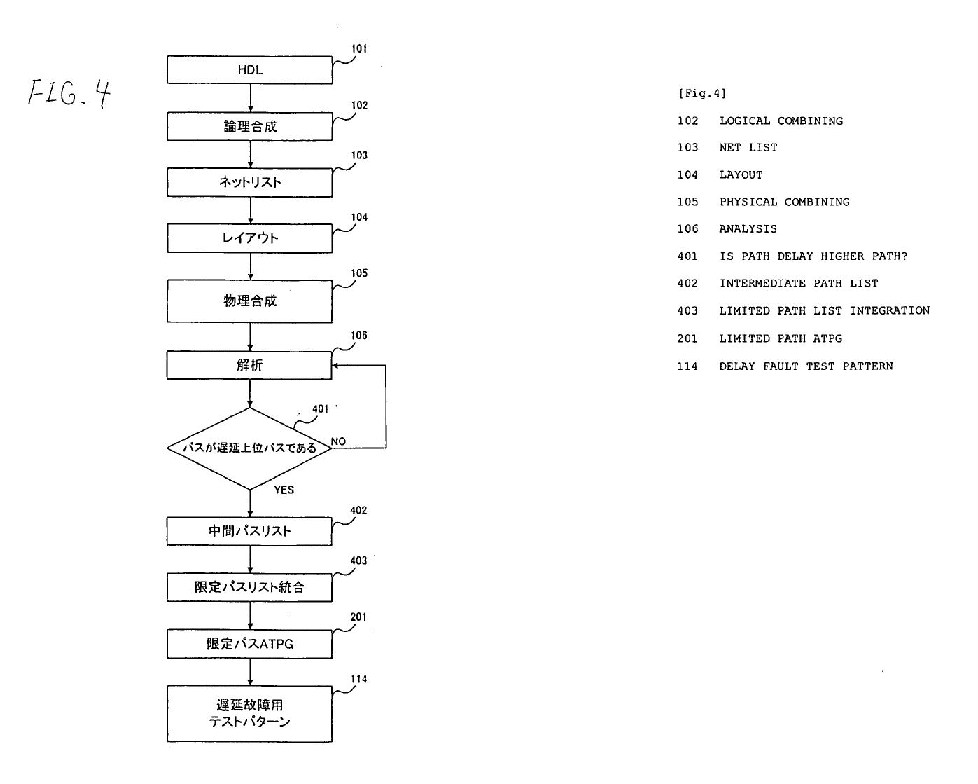

FIG. 4 through FIG. 9 are flow charts which show a path delay test method relating to a second embodiment of the invention. HDL 101 through a timing analyzing process 106, and a process of automatically generating a delay fault test pattern 114 by a limited path ATPG process 201 are the same as those in the first embodiment.

A different point in the second embodiment from the first embodiment is such a point that a path, which satisfies a specific delay fault factor condition, is extracted from critical paths which can be confirmed by the timing analyzing process 106, and this is integrated with a critical path list which was extracted under another delay fault factor condition, and then, the delay fault test pattern 114 is automatically generated by the limited path ATPG process 201.

In FIG. 4, 401 designates a path extracting process under a specific condition, and a path limiting process of extracting a higher order path of a critical path in accordance with a delay value of a path. In addition, 402 designates an intermediate path list which was extracted by the path limiting process 401, and 403 designates a limited path list integrating process of merging and integrating with a path which was extracted under another delay fault factor condition.

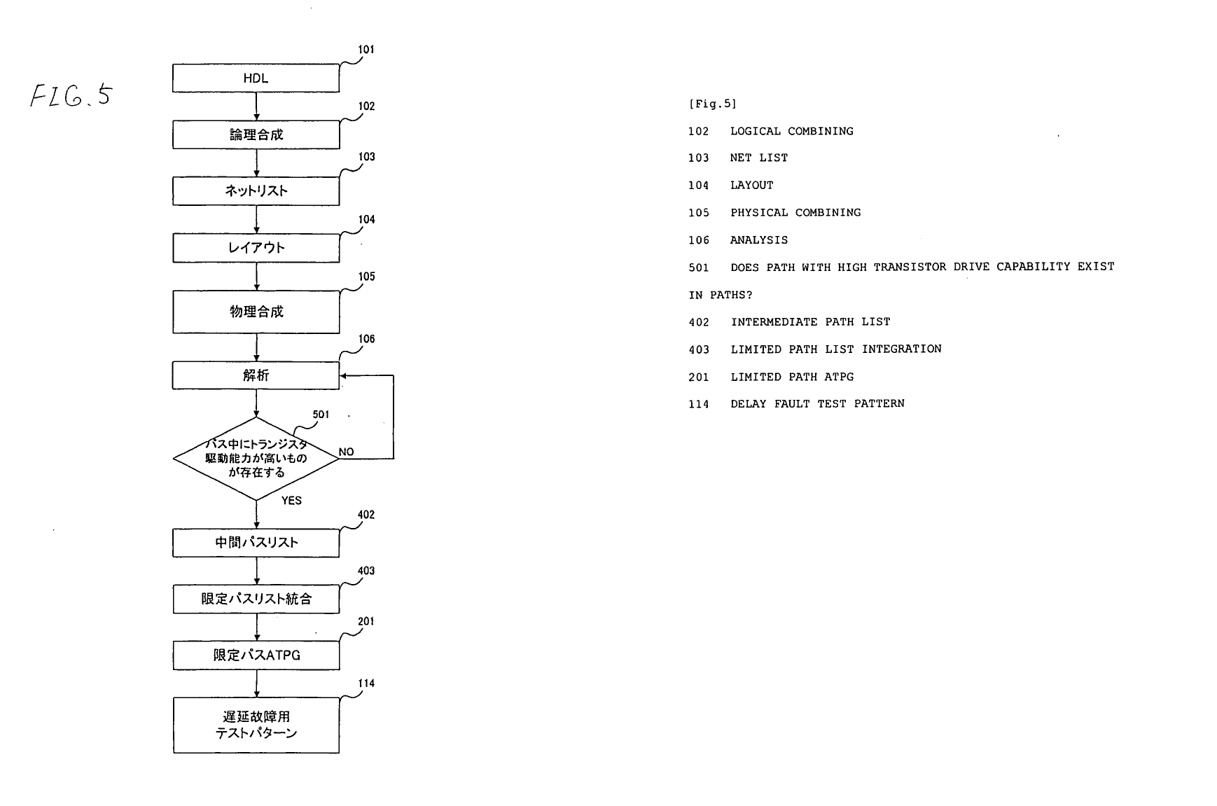

In FIG. 5, 501 designates a path extracting process under a specific condition, and a path limiting process of, on the occasion that there exists a cell with high current drive capability of a transistor in a critical path which can be confirmed by the analyzing process 106, extracting the path. The cell with high current drive capability has a low ON-resistance of a transistor, and, in case that process fluctuation was generated in a via resistance and a wiring resistance, receives its influence widely, and there is need to take a countermeasure to this.

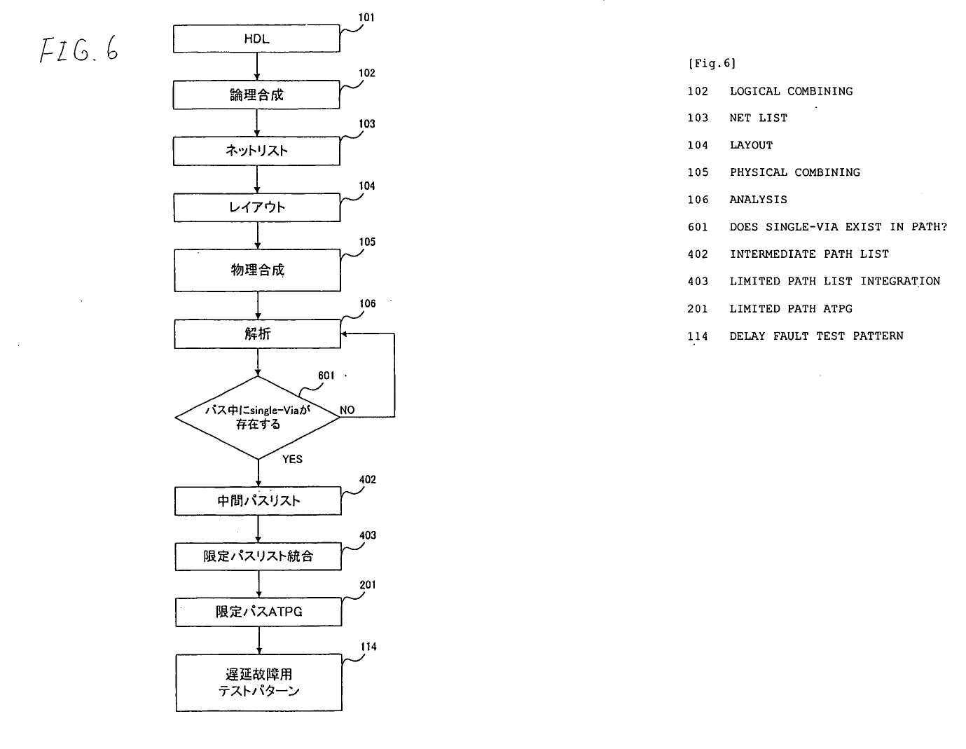

In FIG. 6, 601 designates a path extracting process under a specific condition, and a path limiting process of, on the occasion that there exists a place which was connected by a single via in a critical path which can be confirmed by the analyzing process 106, extracting the path. At the place which was connected by a single via, a resistance value increases clearly in case that a via connection defect occurred, and therefore, there is high possibility that a delay fault is realized, and its countermeasure is necessary.

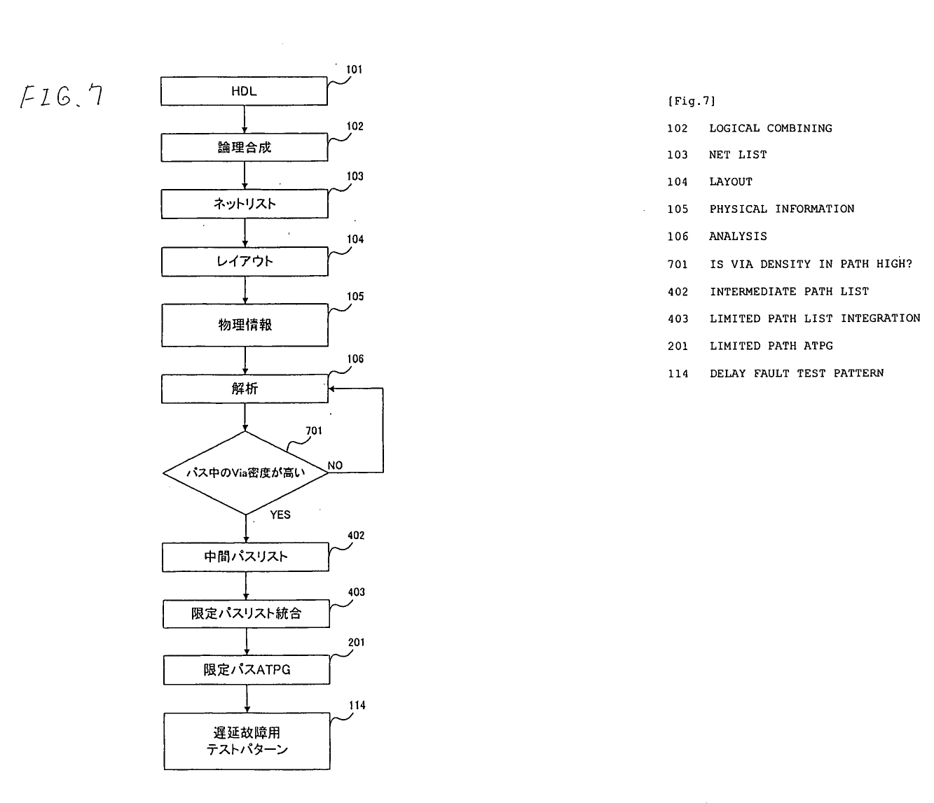

In FIG. 7, 701 designates a path extracting process under a specific condition, and a path limiting process of, on the occasion that there exists a place with high via density in a critical path which can be confirmed by the analyzing process 106, extracting the path. It is because connection defect probability is high at the place with high via density.

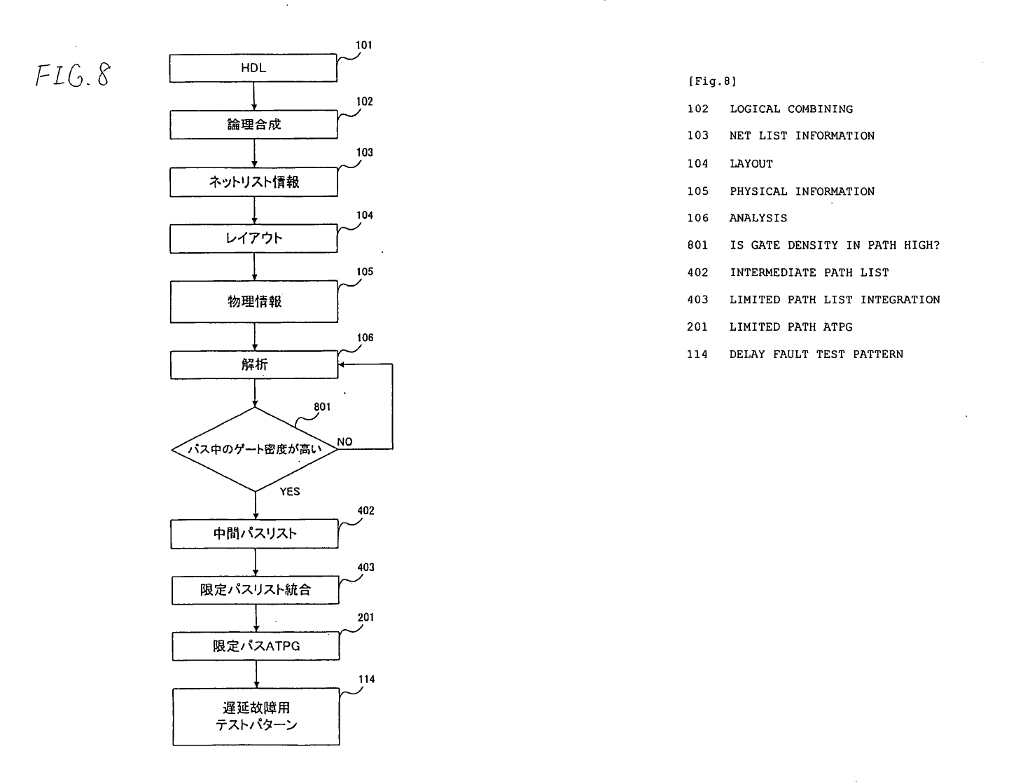

In FIG. 8, 801 designates a path extracting process under a specific condition, and a path limiting process of, on the occasion that there exists a place with high gate density in a critical path which can be confirmed by the analyzing process 106, extracting the path. It is because via connection defect probability and probability of wiring soft short (short circuit which is not short-circuited completely and connected through high resistance) are high at the place with high gate density.

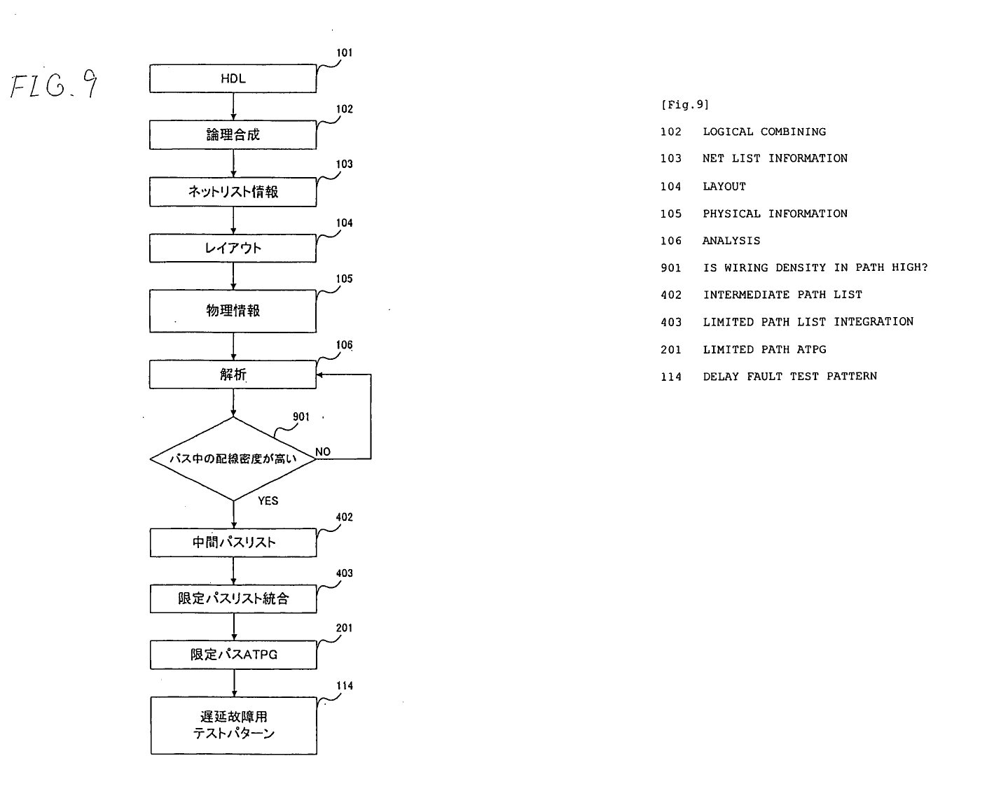

In FIG. 9, 901 designates a path extracting process under a specific condition, and a path limiting process of, on the occasion that there exists a place with high wiring density in a critical path which can be confirmed by the analyzing process 106, extracting the path. It is because wiring soft short probability is high at the place with high wiring density.

### Third Embodiment

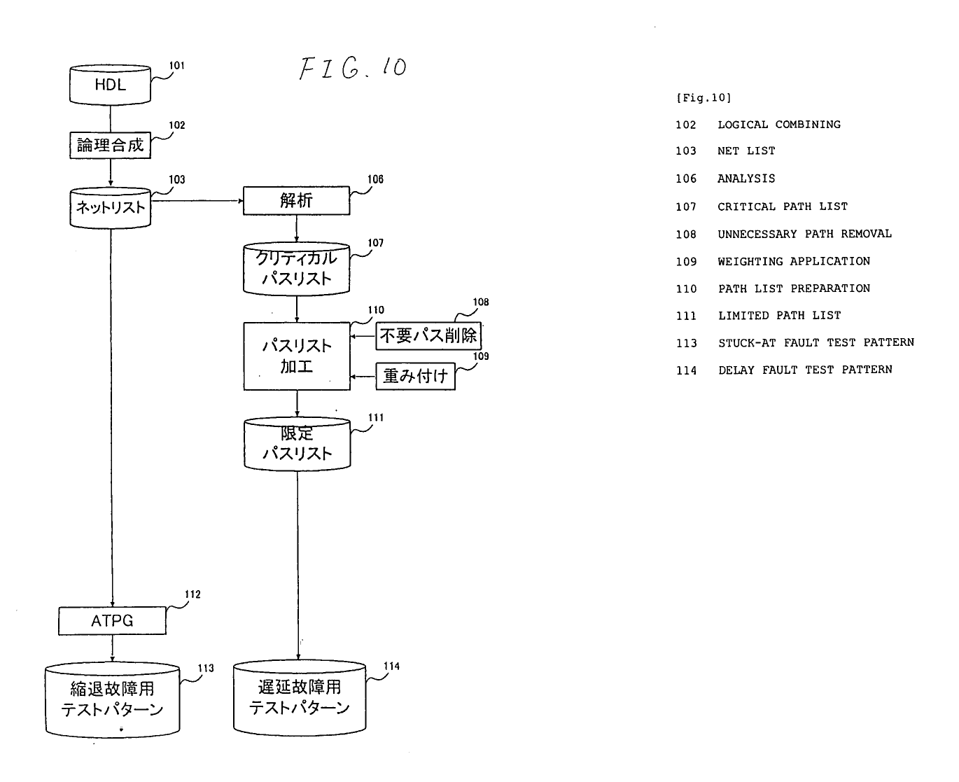

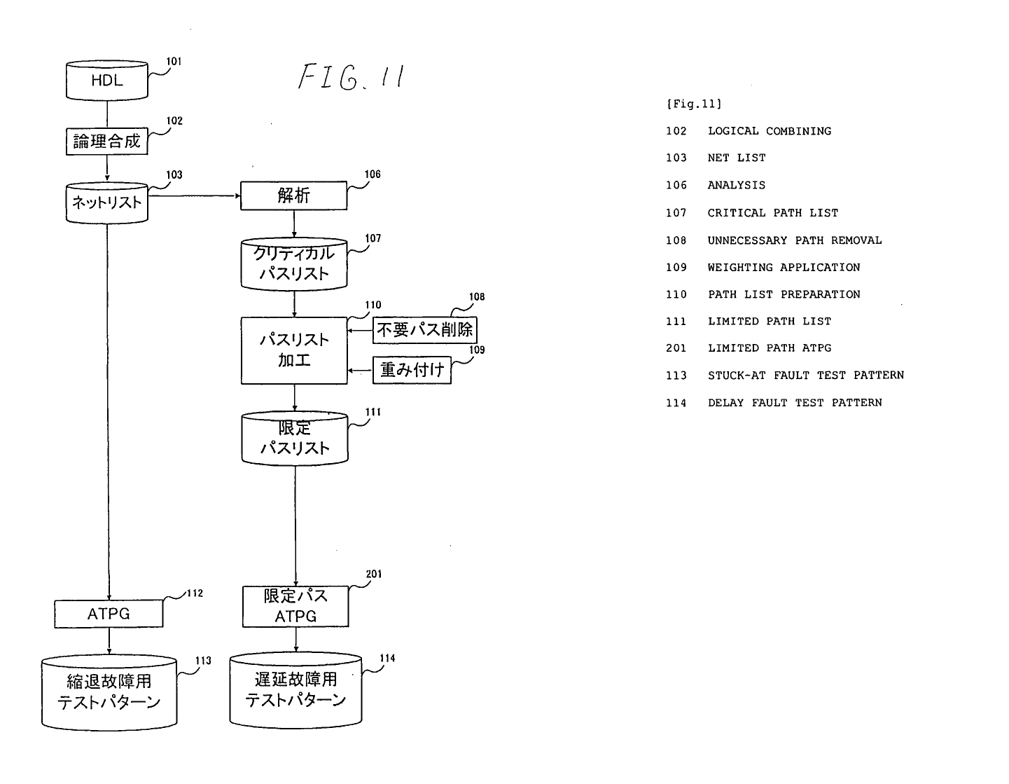

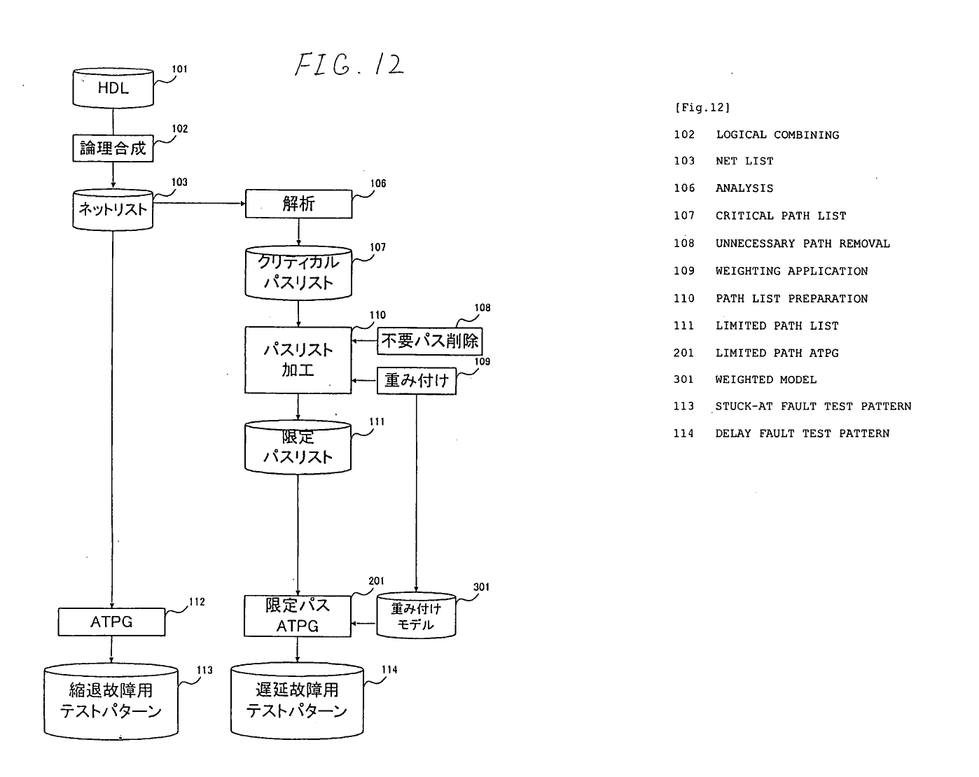

FIG. 10 through FIG. 12 are flow charts which show a path delay test method relating to a third embodiment of the invention. They correspond to FIG. 1 through FIG. 3 of the first embodiment, respectively, and comparing to the first embodiment, the layout process 104 and the physical combining process 105 are removed from each of them.

In this embodiment, path limiting information is obtained from logical combining information without depending on physical combining information as in the first embodiment. In case of such a design policy that physical consideration is applied to a wiring, a via etc. and a margin was setup sufficiently, a test pattern is generated by timing information after logical combining, which has a larger merit in a development schedule of a semiconductor integrated circuit, as compared to such a case that a test pattern was generated by timing information after physical combining.

In this manner, a path with critical timing is extracted by use of timing information after logical combining, and a path is reduced to and weighting is applied to the extracted path, and thereby, a test pattern is reduced. A test pattern is generated only as to the limited path, and a shipping test is carried out, and thereby, it is possible to reduce the number of design man-hours and test cost over maintaining quality of a product.

### Fourth Embodiment

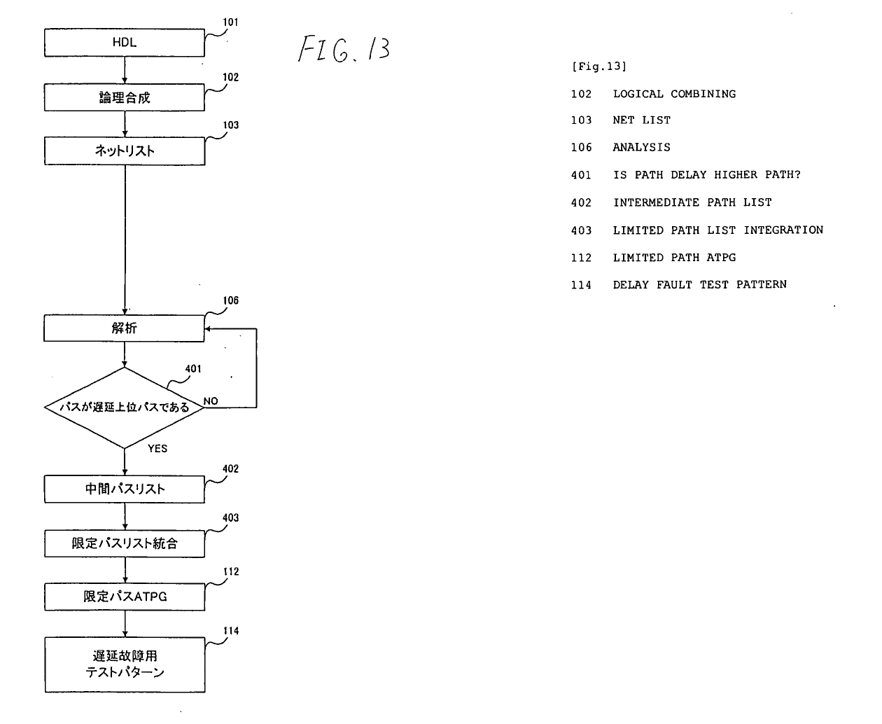

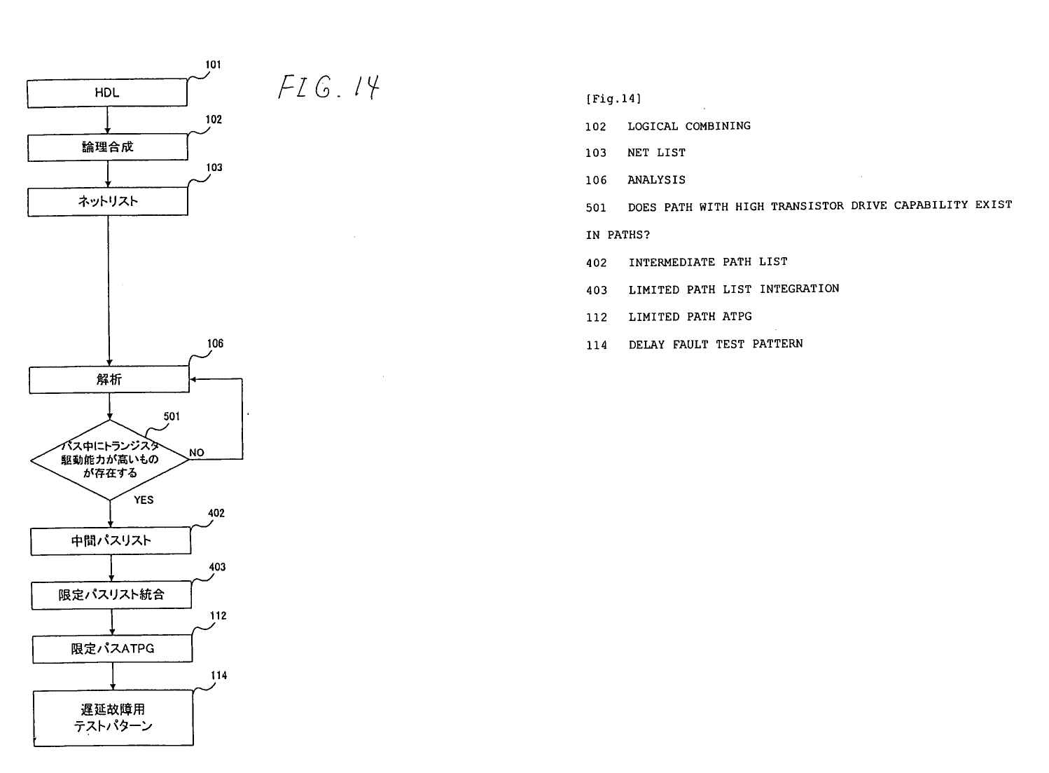

FIG. 13 and FIG. 14 are flow charts which show a path delay test method relating to a fourth embodiment of the invention. They correspond to FIG. 4 and FIG. 5 of the second embodiment, respectively, and comparing with the second embodiment, the layout process 104 and the physical combining process 105 are removed from each of them.

In this case, in the same manner as in the third embodiment, information for extracting a path which satisfies a specific condition is obtained from logical combining information without depending on physical combining information as in the second embodiment. In case of such a design policy that physical consideration is applied to a wiring, a via etc. and a margin was set up sufficiently, a test pattern is generated by timing information after logical combining, which has a larger merit in a development schedule of a semiconductor integrated circuit, as compared to such a case that a test pattern was generated by timing information after physical combining.

In such manner, a path with critical timing is extracted by use of timing information after logical combining, and a path is reduced to and weighting is applied to the extracted path, and thereby, a test pattern is reduced. A test pattern is generated only as to the limited path, and a shipping test is carried out, and thereby, it is possible to reduce the number of design man-hours and test cost over maintaining quality of a product.

According to a path delay test method of the invention, as to a critical path which was extracted from design information, a path is reduced and weighting is applied, and thereby, a test pattern is reduced, and a test pattern is generated only to this limited critical path, and thereby, it is possible to effectively generate a delay fault test pattern, and by carrying out a shipping inspection by use of this test pattern, it has such an advantage that a substantial improvement effect is obtained in all of a quality aspect, a development schedule aspect, and a cost aspect, and it is useful as a test technology etc. of a semiconductor product.

1. A path delay test method comprising:
extracting physical information of a circuit and a critical path to guaranteed operating frequency, from layout information which was generated by a net list of a semiconductor integrated circuit;
sorting out a critical path in which a delay fault is envisaged, from the critical path, on the basis of the physical information; and
generating a test pattern only to the critical path which was sorted out.

2. The path delay test method according to claim 1, wherein generation of the test pattern is carried out by use of automatic test pattern generation software.

3. The path delay test method according to claim 2, wherein, on the occasion of generation of the test pattern, a weighting application verification model obtained from critical path sorting information based on said physical information gives a weighting factor of a critical path to the automatic test pattern generation software.

4. The path delay test method according to claim 1, wherein, in sorting of the critical path, whether it is in a higher order of a critical path is used as a judgment condition.

5. The path delay test method according to claim 1, wherein, in sorting of the critical path, whether there exists a cell with high current drive capability in a critical path is used as a judgment condition.

6. The path delay test method according to claim 1, wherein, in sorting of the critical path, whether there exists a place which was connected by a single via in a critical path is used as a judgment condition.

7. The path delay test method according to claim 1, wherein, in sorting of the critical path, whether a critical path exists in an area where a via density is high is used as a judgment condition.

8. The path delay test method according to claim 1, wherein, in sorting of the critical path, whether a critical path exists in an area where a gate density is high is used as a judgment condition.

9. The path delay test method according to claim 1, wherein, in sorting of the critical path, whether a critical path exists in an area where a wiring density is high is used as a judgment condition.

10. A path delay test method comprising:
extracting a critical path to guaranteed operating frequency, from a logically combined net list of a semiconductor integrated circuit;
sorting out a critical path in which a delay fault is envisaged, from the critical path, on the basis of circuit information of the logical combining; and
generating a test pattern only to the critical path which was sorted out.

11. The path delay test method according to claim 10, wherein generation of the test pattern is carried out by use of automatic test pattern generation software.

12. The path delay test method according to claim 11, wherein, on the occasion of generation of the test pattern, a weighting application verification model obtained from critical path sorting information based on said physical information gives a weighting factor of a critical path to the automatic test pattern generation software.

13. The path delay test method according to claim 10, wherein, in sorting of the critical path, whether it is in a higher order of a critical path is used as a judgment condition.

14. The path delay test method according to claim 10, wherein, in sorting of the critical path, whether there exists a cell with high current drive capability in a critical path is used as a judgment condition.

15. A test method of a semiconductor integrated circuit comprising sorting of a delay fault test pattern in consideration of delay increase due to a structural defect of a semiconductor integrated circuit.
